(19) United States
(12) Patent Application Publication
(10) Pub. No.: US 2021/0265585 A1
(43) Pub. Date: Aug. 26, 2021

(54) ORGANIC LIGHT-EMITTING DIODE (OLED) DISPLAY PANEL, ELECTRONIC DEVICE AND MANUFACTURING METHOD

(71) Applicants: Shanghai Tianma AM-OLED Co., Ltd., Shenghai (CN); Tianma Micro-Electronics Co., Ltd., Shenzhen (CN)

(72) Inventors: Miao WANG, Wuhan (CN); Yuji HAMADA, Shanghai (CN); Xiangcheng WANG, Shanghai (CN); Wei HE, Shanghai (CN); Jinghua NIU, Shanghai (CN); Chen LIU, Shanghai (CN); Ying LIU, Shanghai (CN)

(21) Appl. No.: 17/237,873

(22) Filed: Apr. 22, 2021

Related U.S. Application Data
(62) Division of application No. 15/464,701, filed on Mar. 21, 2017.

(30) Foreign Application Priority Data
Dec. 16, 2016 (CN) 201611168770.2

(51) Int. Cl. H01L 51/50

(52) U.S. Cl. CPC H01L 51/5096; H01L 51/0072; H01L 51/5004

(57) ABSTRACT

The present disclosure provides an OLED display panel, an electronic device, and a manufacturing method. The OLED display panel comprises a first electrode, a light-emitting layer, a first function layer, and a second electrode. The first function layer includes at least a first-type blocking layer disposed adjacent to the light-emitting layer. A first guest material is doped into a host material of the first-type blocking layer, and a ratio of a second-type carrier mobility of the host material over a second-type carrier mobility of the first guest material is greater than or equal to about 10. The first-type is a hole-type and the second-type is an electron-type.

### CROSS-REFERENCES TO RELATED APPLICATIONS

This application is a divisional of U.S. patent application Ser. No. 15/464,701, filed on Mar. 21, 2017, which claims the priority of Chinese Patent Application No. CN201611168770.2, filed on Dec. 16, 2016, the entire contents of which are incorporated herein by reference.

### FIELD OF THE DISCLOSURE

The present disclosure generally relates to the display technology and, more particularly, relates to an OLED display panel, an electronic device and a manufacturing method thereof.

### BACKGROUND

Generally, the structure of an organic electroluminescent device often include an anode, an auxiliary function layer (e.g., a hole transport layer, an electron transport layer, and an electron injection layer, etc.), a light-emitting layer, and a cathode. When a voltage is applied between the anode and the cathode, the holes and electrons are transported to the light-emitting layer to be recombined to form excitons in the light-emitting layer. Driven by the electric field, the excitons are migrated to transfer the energy to the light-emitting material, thereby stimulating electrons in the light-emitting material to transition from a base state to an excited state. Through radiation inactivation, the energy at the excited state produces photons to emit light.

In an existing organic electroluminescent device, the holes and electrons often pass through the light-emitting layer to reach the cathode and the anode, respectively. The energy carried by such holes and electrons may not be utilized to stimulate the light-emitting material to emit light, reducing the efficiency and life span of the device. At the same time, the recombined holes and electrons often form excitons which diffuse laterally. Some excitons may diffuse to other regions that have not been doped with light-emitting material, such as a hole transport layer or an electron transport layer, then may get attenuated. However, such attenuated excitons do not produce any photons. Thus, the light-emitting efficiency of such organic electroluminescent device may be reduced.

In addition, excessive accumulation of electrons and holes in the hole transport layer and the electron transport layer may cause the materials in the hole transport layer and the electron transport layer to have an unstable charged state. Irreversible chemical reaction is likely to occur to such charged material, and the material properties may change or deteriorate. As a result, a reduction in efficiency and life span of the device may be obviously observed.

The disclosed OLED display panel, electronic device and manufacturing method are directed to solve one or more problems set forth above and other problems.

### BRIEF SUMMARY OF THE DISCLOSURE

One aspect of the present disclosure provides an OLED display panel, comprising a first electrode, a light-emitting layer, a first function layer, and a second electrode. The first function layer includes at least a first-type blocking layer disposed adjacent to the light-emitting layer. A first guest material is doped into a host material of the first-type blocking layer, and a ratio of a second-type carrier mobility of the host material over a second-type carrier mobility of the first guest material is greater than or equal to about 10. The first-type is a hole-type and the second-type is an electron-type, or the first-type is an electron-type and the second-type is a hole-type.

Another aspect of the present disclosure provides an electronic device, including a disclosed OLED display panel.

Another aspect of the present disclosure provides a manufacturing method for the OLED display panel, comprising sequentially forming a first electrode, a light-emitting layer, a first function layer, and a second electrode, or sequentially forming a second electrode, a first function layer, a light-emitting layer, and a first electrode. The first function layer includes at least a first-type blocking layer disposed adjacent to the light-emitting layer, a first guest material is doped into a host material of the first function layer, and a ratio of a second-type carrier mobility of the host material over a second-type carrier mobility of the first guest material is greater than or equal to about 10. The first-type is a hole-type and the second-type is an electron-type, or the first-type is an electron-type and the second-type is a hole-type.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a cross-sectional view of an exemplary OLED display panel according to the disclosed embodiments;

FIG. 2 illustrates a life span measurement result chart comparing two existing OLED display panels and an exemplary electron-rich OLED display panel according to the disclosed embodiments;

FIG. 3 illustrates a current density vs external quantum efficiency measurement result chart comparing two existing OLED display panels and an exemplary display panel shown in FIG. 2;

FIG. 4 illustrates a cross-sectional view of another exemplary OLED display panel according to the disclosed embodiments;

FIG. 5 illustrates a life span measurement result chart comparing an existing OLED display panel and an exemplary hole-rich OLED display panel according to the disclosed embodiments;

FIG. 6 illustrates a current density vs external quantum efficiency measurement result chart comparing an existing OLED display panel and an exemplary display panel shown in FIG. 5;

FIG. 7 illustrates a cross-sectional view of another exemplary OLED display panel according to the disclosed embodiments;

FIG. 8 illustrates a schematic view of an exemplary electronic device according to the disclosed embodiments;

FIG. 9 illustrates a flow chart of an exemplary manufacturing method for an exemplary OLED display panel according to the disclosed embodiments;

FIG. 10 illustrates a flow chart of another exemplary method for manufacturing an exemplary OLED display panel according to the disclosed embodiments; and

FIG. 11 illustrates a flow chart of another exemplary method for manufacturing an exemplary OLED display panel according to the disclosed embodiments.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts. It should be understood that the exemplary embodiments described herein are only intended to illustrate and explain the present invention and not to limit the present invention. In addition, it should also be noted that, for ease of description, only part, but not all, of the structures associated with the present invention are shown in the accompanying drawings.

The present disclosure provides an OLED display panel comprising at least a first electrode, a light-emitting layer, a first function layer, and a second electrode, which are disposed in layers. The first function layer may include at least a first-type blocking layer, which may be disposed adjacent to the light-emitting layer. A first guest material may be doped in the first-type blocking layer. In the first-type blocking layer, the ratio of the mobility of the second-type carrier inside the host material over the mobility of the second-type carrier inside the first guest material may be greater than or equal to about 10.

In one embodiment, the above-mentioned first-type may be a hole-type, and the above-mentioned second-type may be an electron-type. Accordingly, the first electrode may be an anode of an OLED device, and the second electrode may be a cathode of the OLED device. In another embodiment, the above-mentioned first-type may be an electron-type, and the above-mentioned second-type may be a hole-type. Accordingly, the first electrode may be a cathode of an OLED device, and the second electrode may be an anode of the OLED device. The anode may be a transparent conductive film made of ITO, AZO, or IZO. The cathode may be made of Al, Pt, Au, Ag, MgAg alloy, YbAg alloy, or Ag rare earth metal alloy. In addition to the first-type blocking layer, the first function layer may further include at least one of a second-type injection layer, and a second-type transport layer.

In one embodiment, to prevent the excitons formed by recombined electrons and holes from diffusing laterally to other layers on both sides of the light-emitting layer, the locations where excitons are recombined to emit light may be adjusted in an electron-rich OLED device or a hole-rich OLED device.

For example, in the electron-rich OLED device, the OLED display panel according to the present disclosure may comprise at least a first electrode, a light-emitting layer, a first function layer, and a second electrode, which are disposed in layers. The first function layer may include at least a hole blocking layer, which may be disposed adjacent to the light-emitting layer. A first guest material may be doped in the hole blocking layer. In the hole blocking layer, the ratio of the electron mobility of the host material over the electron mobility of the first guest material may be configured to be greater than or equal to about 10.

Because the hole blocking layer is disposed between the light-emitting layer and the second electrode, the hole blocking layer may be able to prevent an excessive number of holes from passing through the light-emitting layer to reach the side of the light-emitting layer far away from the first electrode. Thus, the excitons may be prevented from diffusing to regions other than the light-emitting layer and, accordingly, the utilization of the excitons and the light-emitting efficiency of the device may be improved.

Further, the guest material (i.e., the first guest material) may be doped into the hole blocking layer. In the hole blocking layer, the ratio of the electron mobility of the host material over the electron mobility of the first guest material may be configured to be greater than or equal to about 10. That is, the guest material having a smaller electron mobility than the host material may be doped in the hole blocking layer. For the electron-rich OLED device, the guest material having a substantially small electron mobility may reduce the electron movement, adjust the balance of the electrons and holes in the light-emitting layer, confine the electron and hole recombination in the light-emitting layer, and increase the light-emitting efficiency and life span of the device.

Further, the guest and host materials in the hole blocking layer may have a higher triplet state energy level than the light-emitting layer, preventing the excitons formed by the electron and hole recombination from diffusing to organic layers other than the light-emitting layer. Thus, the efficiency of the organic electroluminescent device may be improved.

For example, in the hole-rich OLED device, the OLED display panel according to the present disclosure may comprise at least a first electrode, a light-emitting layer, a first function layer, and a second electrode, which are disposed in layers. The first function layer may include at least an electron blocking layer, which may be disposed adjacent to the light-emitting layer. A first guest material may be doped into the electron blocking layer. In the electron blocking layer, the ratio of the hole mobility of the host material over the hole mobility of the first guest material may be configured to be greater than or equal to about 10.

Because the electron blocking layer may be disposed between the light-emitting layer and the second electrode, the electron blocking layer may be able to prevent an excessive number of electrons from passing through the light-emitting layer to reach the side of the light-emitting layer far away from the first electrode. Thus, the excitons may be prevented from diffusing to regions other than the light-emitting layer and, accordingly, the excitons utilization and the light-emitting efficiency of the device may be improved.

Further, the guest material (i.e., first guest material) may be doped in the electron blocking layer, and in the electron blocking layer, the ratio of the hole mobility of the host material over the hole mobility of the guest material may be configured to be greater than or equal to about 10. That is, the guest material having a smaller hole mobility than the host material may be doped into the electron blocking layer. For the hole-rich OLED device, the guest material having a substantially small hole mobility may reduce the hole movement, adjust the balance of the electrons and holes in the light-emitting layer, confine the electron and hole recombination in the light-emitting layer, and increase the light-emitting efficiency and life span of the device.

Further, the guest and host materials in the electron blocking layer may have a higher triplet state energy level than the light-emitting layer, preventing the excitons formed by the electron and hole recombination from diffusing to organic layers other than the light-emitting layer. Thus, the efficiency of the organic electroluminescent device may be improved.

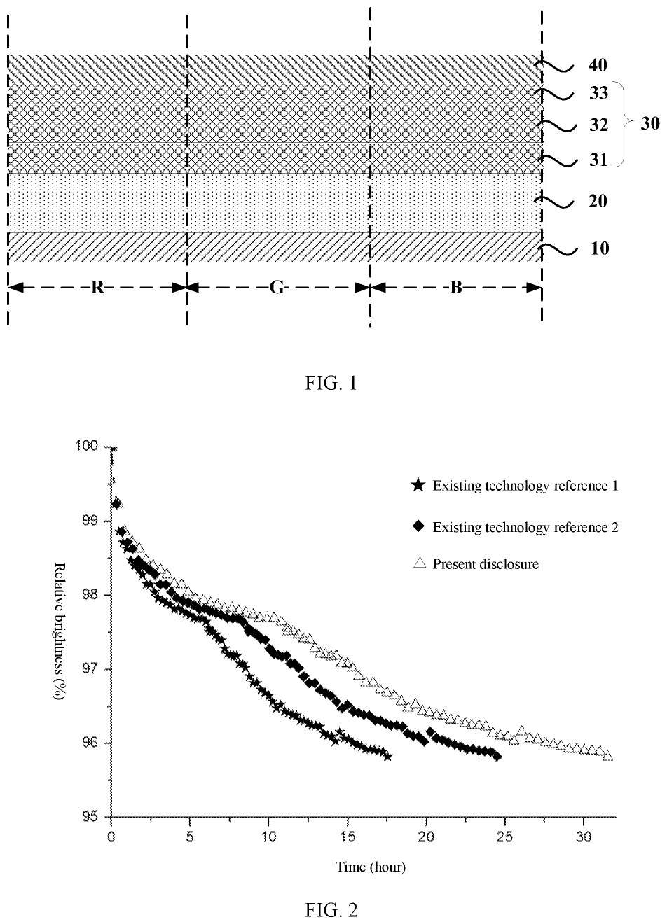

FIG. 1 illustrates a cross-sectional view of an exemplary OLED display panel according to the present disclosure. As shown in FIG. 1, the OLED display panel may include at least a first electrode 10, a light-emitting layer 20, a first function layer 30, and a second electrode 40. Other appropriate components may also be included.

In particular, the first function layer 30 may include at least a hole blocking layer 31. The hole blocking layer 31 may be disposed adjacent to the light-emitting layer 20. In one embodiment, as shown in FIG. 1, the hole blocking layer 31 may be disposed between the light-emitting layer 20 and the second electrode 40 of the OLED display panel, such that an excessive number of holes may be prevented from passing through the light-emitting layer 20 to reach the second electrode 40. Thus, the holes may be effectively confined to the light-emitting layer 20, the exciton yield may be increased, and the light-emitting efficiency may be improved.

In general, the electrons and holes in the OLED devices are not balanced. For the hole-rich OLED device, the electrons and holes may be recombined in a region or the surface of the light-emitting layer 20 which is adjacent to the second electrode 40, such that the electrons and holes may be recombined in a narrow region. When a current density is substantially high, the exciton density in the narrow region may be substantially high. Excitons may interact with each other to cause, for example, triplet-triplet annihilation, and triplet-singlet annihilation, etc., such that the exciton utilization may be reduced, and the efficiency of the OLED display panel may be reduced accordingly. At the same time, a large number of excitons accumulated in the narrow region may cause the light-emitting material to deteriorate and, thus, the life span of the OLED display device may be reduced.

Further, in one embodiment, a first guest material A may be doped in a host material B of the hole blocking layer 31. In the hole blocking layer 31, the ratio of the electron mobility (μₑ_B) corresponding to the host material B over the electron mobility (μₑ_A) corresponding to the first guest material A may be configured to be greater than or equal to about 10. That is, the first guest material A having a smaller electron mobility (μₑ_A) than the host material B may be doped in the hole blocking layer 31.

In the hole blocking layer 31 of the electron-rich device, the first guest dopant material A, which has a smaller electron mobility (μₑ_A) than the guest material B, may reduce the electron movement, adjust the balance of the electrons and holes in the light-emitting layer 20, confine the electron and hole recombination in the light-emitting layer 20, and increase the light-emitting efficiency and life span of the device.

In one embodiment, the first electrode 10 may be an anode, and the second electrode 40 may be a cathode. Optionally, the first function layer 30 may also include at least one of an electron injection layer 33, and an electron transport layer 32. For example, referring to FIG. 1, the electron transport layer 32 may be disposed between the hole blocking layer 31 and the electron injection layer 33. The electron injection layer 33 may be disposed between the electron transport layer 32 and the second electrode 40.

The hole blocking layer 31 may include electron transport type materials. The hole blocking layer 31 may include at least one of metal complexes, oxadiazole-based materials, imidazole-based materials, triazole-based materials, pyridine-based materials, o-phenanthroline-based materials, organoboron-based materials, and organosilicon-based materials.

The host material B of the hole blocking layer 31 may include, for example, at least one of 3,3′-[5′-[3-(3-pyridinyl)phenyl][1,1′:3′,1″-terpheny1]-3,3″-diy1]bispyridine (TmPyPB), 4,4-bis(9-carbazolyl)-1,1′-biphenyl (BCP), 4,6-bis(3,5-di(pyridine-4-yl)phenyl)-2-MethylpyriMidine (B4PyMPM), star oxadiazole, and 1,3,5-tris(N-phenyl-2-benzimidazole) benzene (TPBi). The first guest material A of the hole blocking layer 31 may include, for example, at least one of 8-hydroxyquinoline aluminum (Alq3), 8-hydroxyquinoline lithium (Liq), 2-(4-biphenyl)-5-phenyl oxadiazole (PBD), 2,5-bis-(4-naphthyl)-1,3,4-oxadiazole (BND), tris-(2,3,5,6-trimethyl)phenylboron, and 2,5-diaryl silicon.

The skeletal structural formula of 4,6-bis(3,5-di(pyridine-4-yl)phenyl)-2-MethylpyriMidine (B4PyMPM) is

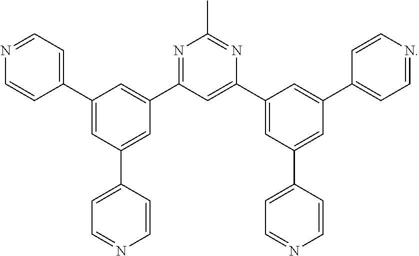 [SMILES: Cc1nc(-c2cc(-c3ccncc3)cc(-c3ccncc3)c2)cc(-c2cc(-c3ccncc3)cc(-c3ccncc3)c2)n1]

The skeletal structural formula of 2,5-bis-(4-naphthyl)-1,3,4-oxadiazole (BND) is

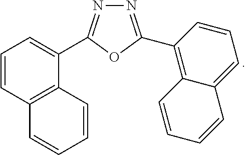 [SMILES: c1ccc2c(-c3nnc(-c4cccc5ccccc45)o3)cccc2c1]

The skeletal structural formula of 2,5-diaryl silicon is

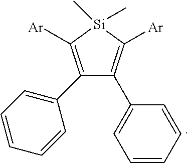

The skeletal structural formula of star oxadiazole is

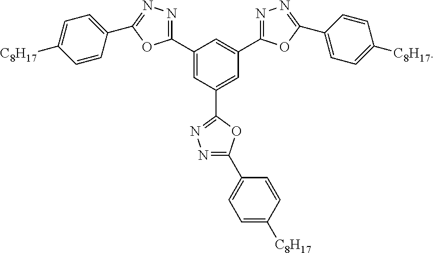

The skeletal structural formula of tris-(2,3,5,6-trimethyl)phenylboron is

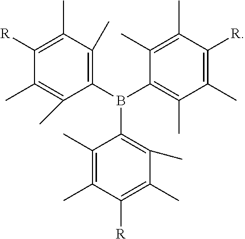

The skeletal structural formula of 1,3,5-tris(N-phenyl-2-benzimidazole) benzene (TPBi) is

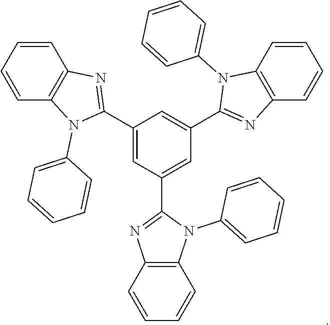 [SMILES: c1ccc(-n2c(-c3cc(-c4nc5ccccc5n4-c4ccccc4)cc(-c4nc5ccccc5n4-c4ccccc4)c3)nc3ccccc32)cc1 ; "."]

In one embodiment, the highest occupied orbital level HOMO_{B} of the host material B of the hole blocking layer 31 may be at least approximately 0.3 eV higher than the highest occupied orbital level HOMO_{C} of the host material C of the light-emitting layer 20, and the highest occupied orbital level HOMO_{A} of the first guest material A of the hole blocking layer 31 may be at least approximately 0.3 eV higher than the highest occupied orbital level HOMO_{C} of the host material C of the light-emitting layer 20, such that the hole blocking layer 31 may be effective in blocking hole movement.

In the electroluminescent process, the singlet and triplet excitons may be generated in a ratio of approximately 1:3 and, thus, it is critical to effectively utilize the triplet excitons to improve the device efficiency. Thus, the triplet state energy level T_{B} of the host material B of the hole blocking layer 31 may be configured to be greater than the triplet state energy level T_{C} of the host material C of the light-emitting layer 20, and the triplet state energy level T_{A} of the first guest material A of the hole blocking layer 31 may be configured to be greater than the triplet state energy level T_{C} of the host material C of the light-emitting layer 20, which may improve the utilization rate of the triplet state excitons from the device structure perspective.

After the triplet state excitons are generated in the light-emitting layer 20, through utilizing the higher triplet state energy level property of the hole blocking layer 31, the triplet state excitons in the light-emitting layer 20 may be prevented from being transported to other layers (e.g., the electron transport layer 32) outside the light-emitting layer 20. Thus, the exciton utilization rate of the device may be improved, and the light-emitting efficiency of the device may be increased.

The content of the host material B in the hole blocking layer 31 may be determined according to various application scenarios. In one embodiment, the content (i.e., weight percentage) of the host material B in the hole blocking layer 31 may be configured to be greater than or equal to about 90%. Provided that the content of the host material B effectively confine the holes in the light-emitting layer 20, through doping the first guest material A into the host material B of the hole blocking layer 31, the electron injection rate into the light-emitting layer 20 may be reduced, and the electrons and holes in the light-emitting layer 20 may be balanced, such that the electrons and holes may be recombined in the center of the light-emitting layer 20. The exciton binding region may be widened, and the efficiency and life span of the device may be increased.

In one embodiment, the electron mobility of the host material B and the first guest material A in the hole blocking layer 31 may be configured to be 10⁻⁴ cm⁻²/V·S≤μₑ_B≤10⁻³ cm⁻²/V·S, and μₑ_A≤10⁻⁴ cm⁻²/V·S, respectively. The host material B and the first guest material A may be selected to satisfy the above relationship, such that the efficiency and life span of the device may be increased.

For example, μₑ_B may be approximately 10⁻³ cm⁻²/V·S, and μₑ_A may be approximately 10⁻⁴ cm⁻²/V·S. The hole blocking layer 31 may have a thickness ranging approximately between the 1 nm and 20 nm. For example, the hole blocking layer 31 may have a thickness of about 5 nm. The thickness of the hole blocking layer 31 may be selected according to various application scenarios. The hole blocking layer 31 having a substantially thin thickness may be ineffective to block the hole movement, and the hole blocking layer 31 having a substantially thick thickness may not only block the hole movement, but also increase the operating voltage of the device.

FIG. 2 illustrates a life span measurement result chart comparing two existing OLED display panels and an exemplary electron-rich OLED display panel according to the present disclosure. The device of the existing technology reference 1 in FIG. 2 may include a first electrode, a hole injection layer, a hole transport layer, a light-emitting layer, an electron transport layer, an electron injection layer, and a second electrode.

The first electrode of the existing technology reference 1 may be made of indium tin oxide (ITO), and may have a thickness of about 150 nm. The hole injection layer may be made of N,N-diphenyl-N,N-bis(1-naphthyl)-1,1-diphenyl-4,4-diamine (NPB) doped with 2,3,5,6-tetrafluoro-7,7′,8,8′-tetracyanoquinodimethane (F4-TCNQ). The F4-TCNQ material may have a doping ratio of about 3% by weight. The hole injection layer may have a thickness of about 10 nm. The hole transport layer may be made of NPB, and may have a thickness of about 50 nm.

The host material of the light-emitting layer may be 1,4-bis(5-p-tert-butylphenyl-1,3,4-oxadiazolyl-2)benzene (OXD-7). The guest material may be tris(2-phenylpyridine)iridium (Ir(PPY)₃). Ir(PPY)₃ may have a doping ratio of about 6% by weight. The light-emitting layer may have a thickness of about 25 nm. The electron transport layer may be made of 8-hydroxyquinoline aluminum (Alq3), and may have a thickness of about 40 nm. The electron injection layer may be made of LiF, and may have a thickness of about 1 nm. The second electrode may be made of Al, and may have a thickness of about 200 nm.

Further, the device of the existing technology reference 2 in FIG. 2 may include a first electrode, a hole injection layer, a hole transport layer, an electron blocking layer, a light-emitting layer, a hole blocking layer, an electron transport layer, an electron injection layer, and a second electrode.

The first electrode of the existing technology reference 2 may be made of indium tin oxide (ITO), and may have a thickness of about 150 nm. The hole injection layer may be made of N,N-diphenyl-N,N-bis(1-naphthyl)-1,1-diphenyl-4,4-diamine (NPB) doped with 2,3,5,6-tetrafluoro-7,7′,8,8′-tetracyanoquinodimethane (F4-TCNQ). The F4-TCNQ material may have a doping ratio of about 3% by weight. The hole injection layer may have a thickness of about 10 nm. The hole transport layer may be made of NPB, and may have a thickness of about 50 nm. The electron blocking layer may be made of 4,4′-cyclohexylbis[N,N-bis(4-methylphenyl)aniline] (TAPC), and may have a thickness of about 5 nm.

The host material of the light-emitting layer may be 1,4-bis(5-p-tert-butylphenyl-1,3,4-oxadiazolyl-2)benzene (OXD-7). The guest material may be tris(2-phenylpyridine)iridium (Ir(PPY)₃). Ir(PPY)₃ may have a doping ratio of about 6% by weight. The light-emitting layer may have a thickness of about 25 nm. The hole blocking layer may be made of 2,9-dimethyl-4,7-biphenyl-1,10-phenanthroline (BCP), and may have a thickness of about 5 nm. The electron transport layer may be made of 8-hydroxyquinoline aluminum (Alq3), and may have a thickness of about 40 nm. The electron injection layer may be made of LiF, and may have a thickness of about 1 nm. The second electrode may be made of Al, and may have a thickness of about 200 nm.

Referring to FIG. 2, the OLED display panel according to the present disclosure may include a first electrode, a hole injection layer, a hole transport layer, an electron blocking layer, a light-emitting layer, a hole blocking layer, an electron transport layer, an electron injection layer, and a second electrode.

In one embodiment, the first electrode may be made of indium tin oxide (ITO), and may have a thickness of about 150 nm. The hole injection layer may be made of N,N-diphenyl-N,N-bis(1-naphthyl)-1,1-diphenyl-4,4-diamine (NPB) doped with 2,3,5,6-tetrafluoro-7,7′,8,8′-tetracyanoquinodimethane (F4-TCNQ). The F4-TCNQ material may have a doping ratio of about 3% by weight. The hole injection layer may have a thickness of about 10 nm.

The hole transport layer may be made of NPB, and may have a thickness of about 50 nm. The electron blocking layer may be made of 4,4′-cyclohexylbis[N,N-bis(4-methylphenyl)aniline] (TAPC), and may have a thickness of about 5 nm. The host material of the light-emitting layer may be 1,4-bis(5-p-tert-butylphenyl-1,3,4-oxadiazolyl-2)benzene (OXD-7), and the guest material may be tris(2-phenylpyridine)iridium (Ir(PPY)₃). Ir(PPY)₃ may have a doping ratio of about 6% by weight. The light-emitting layer may have a thickness of about 25 nm.

The host material of the hole blocking layer may be 2,9-dimethyl-4,7-biphenyl-1,10-phenanthroline (BCP), and the guest material may be biphenyl-5-(4-tert-butylphenyl)-1,3,4-oxadiazole (PBD). The PBD material may have a doping ratio of about 10% by weight. The ratio of the electron mobility of the BCP material over the electron mobility of the PBD material may be equal to about 10. The hole blocking layer may have a thickness of about 5 nm. The electron transport layer may be made of 8-hydroxyquinoline aluminum (Alq3), and may have a thickness of about 40 nm. The electron injection layer may be made of LiF, and may have a thickness of about 1 nm. The second electrode may be made of Al, and may have a thickness of about 200 nm.

The skeletal structural formula of N,N-diphenyl-N,N-bis(1-naphthyl)-1,1-diphenyl-4,4-diamine (NPB) forming the hole injection layer is

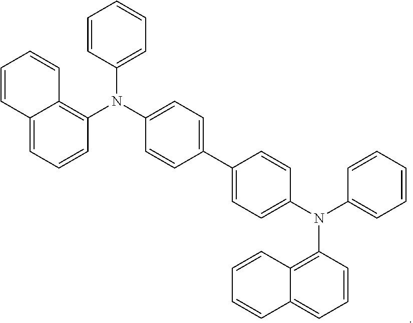 [SMILES: c1ccc(N(c2ccc(-c3ccc(N(c4ccccc4)c4cccc5ccccc45)cc3)cc2)c2cccc3ccccc23)cc1 ; "."]

The skeletal structural formula of 2,3,5,6-tetrafluoro-7,7′,8,8′-tetracyanoquinodimethane (F4-TCNQ) forming the hole injection layer is

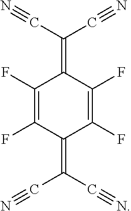 [SMILES: N#CC(C#N)=c1c(F)c(F)c(=C(C#N)C#N)c(F)c1F]

The skeletal structural formula of 1,4-bis(5-p-tert-butylphenyl-1,3,4-oxadiazolyl-2)benzene (OXD-7) forming the light-emitting layer is

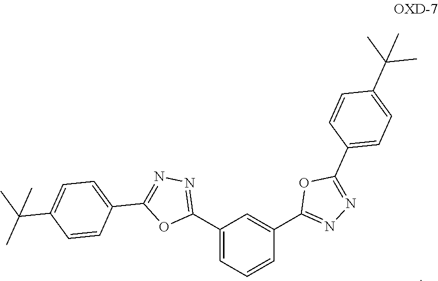 [SMILES: CC(C)(C)c1ccc(-c2nnc(-c3cccc(-c4nnc(-c5ccc(C(C)(C)C)cc5)o4)c3)o2)cc1 ; "."]

The skeletal structural formula of tris(2-phenylpyridine)iridium (Ir(PPY)₃) forming the light-emitting layer is

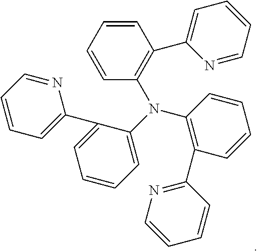 [SMILES: c1ccc(-c2ccccc2N(c2ccccc2-c2ccccn2)c2ccccc2-c2ccccn2)nc1 ; "."]

The skeletal structural formula of 8-hydroxyquinoline aluminum (Alq3) forming the electron transport layer is

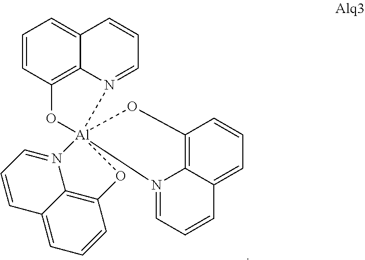

The skeletal structural formula of 4,4′-cyclohexylbis[N,N-bis(4-methylphenyl)aniline] (TAPC) forming the electron blocking layer is

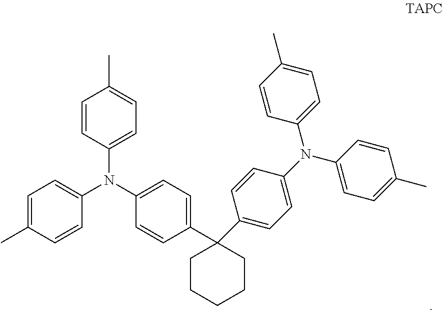

The skeletal structural formula of 2,9-dimethyl-4,7-biphenyl-1,10-phenanthroline (BCP) forming the hole blocking layer is

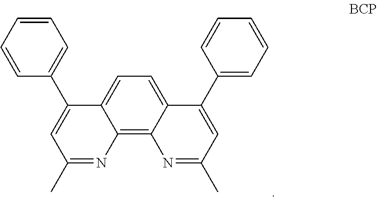 [SMILES: Cc1cc(-c2ccccc2)c2ccc3c(-c4ccccc4)cc(C)nc3c2n1 ; "."]

The skeletal structural formula of biphenyl-5-(4-tert-butylphenyl)-1,3,4-oxadiazole (PBD) forming the hole blocking layer is

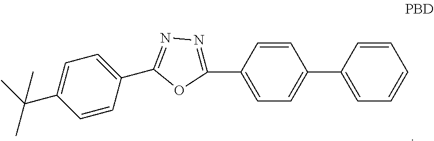 [SMILES: CC(C)(C)c1ccc(-c2nnc(-c3ccc(-c4ccccc4)cc3)o2)cc1 ; "."]

Referring to FIG. 2, the OLED display panel disclosed by the present disclosure and the existing technology references 1 and 2 may be tested under the current density of about 50 mA/cm². In FIG. 2, the abscissa denotes time (unit: hour), and the ordinate denotes the relative luminance. As shown in FIG. 2, the relative luminance of the OLED display panel disclosed by the present disclosure may be attenuated slower than the relative luminance of the existing technology references 1 and 2. After about 15 hours, the relative luminance of the existing technology reference 1 may be attenuated to about 96.1%, and the relative luminance of the existing technology reference 2 may be attenuated to about 96.5%, while the relative luminance of the OLED display panel disclosed by the present disclosure may be attenuated to about 97.2%.

In the existing technology reference 2, because the electron blocking layer and the hole blocking layer are configured on both sides of the light-emitting layer, respectively, the balance of the electrons and holes in the device may be adjusted to certain degree, and an excessive number of electrons and holes passing through the limiting layer may be avoided. Thus, the relative luminance of the existing technology reference 2 may be attenuated slower than the relative luminance of the existing technology reference 1.

Further, the OLED display panel disclosed by the present disclosure may also be applicable to the electron-rich OLED display panel. Because the electron-rich OLED device is electron-rich, the excitons in the light-emitting layer may be located at the interface between the hole transport layer and the light-emitting layer. Thus, in the disclosed embodiments, through introducing an electron blocking layer and a hole blocking layer to the OLED display panel, and doping a guest material having a smaller electron mobility than the host material into the hole blocking layer, the electron movement may be reduced, the balance of the electrons and holes in the light-emitting layer may be adjusted, and the electron and hole recombination may be confined in the light-emitting layer. Accordingly, the efficiency of the organic electroluminescent device may be further improved.

Thus, the disclosed OLED display panel may be able to be operated at a relatively low operating voltage, leading to a slower attenuation of the relative luminance and a longer device life span. In addition, in the disclosed OLED display panel, the electron movement and the hole movement may be further balanced, the material deterioration may be suppressed, and the life span may be extended.

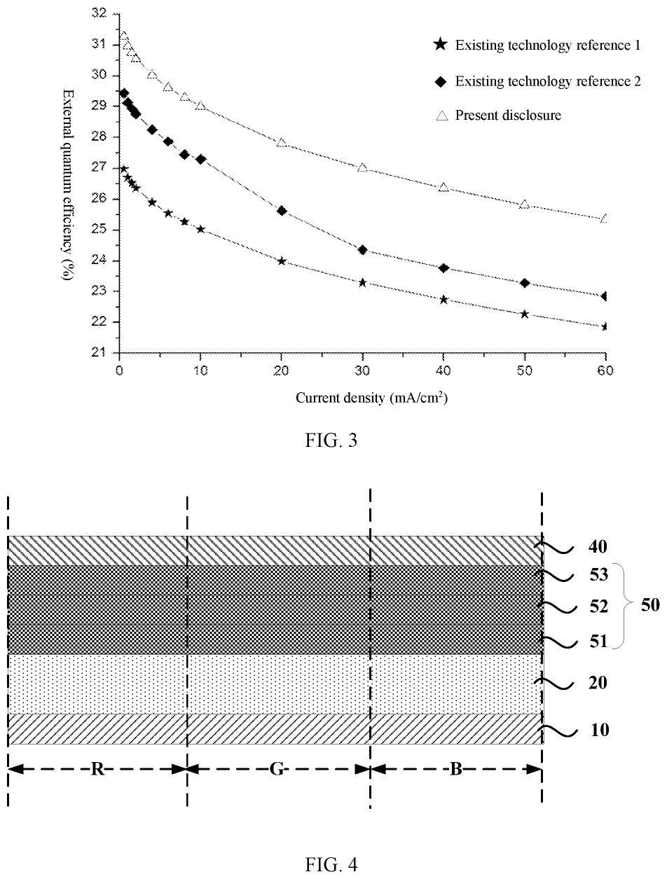

FIG. 3 illustrates a current density vs external quantum efficiency measurement result chart comparing two existing OLED display panels and an exemplary display panel shown in FIG. 2. As shown in FIG. 3, with a same current density, the OLED display panel according to the present disclosure may have a substantially higher external quantum efficiency than the existing technology references 1 and 2. Because the OLED display panel according to the present disclosure has the added electron blocking layer and hole blocking layer, and the hole blocking layer may be doped with a guest material having a relatively small electron mobility, the electrons and holes may be effectively confined inside the light-emitting layer.

That is, the excitons may be prevented from being diffused to other regions outside the light-emitting layer. Thus, the exciton yield may be increased, the balance of the electrons and holes in the device may be adjusted, the electron and hole recombination may be confined in the light-emitting layer, a portion of the excitons formed by the electron and hole recombination may be prevented from being diffused to organic layers on both sides of the light-emitting layer and, accordingly, a higher external quantum efficiency may be achieved.

FIG. 4 illustrates a cross-sectional view of another exemplary OLED display panel according to the present disclosure. The similarities between FIG. 1 and FIG. 4 are not repeated here, while certain difference may be explained.

As shown in FIG. 4, the OLED display panel may include at least a first electrode 10, a light-emitting layer 20, a first function layer 50, and a second electrode 40, which are disposed in layers or a stacked configuration. The first function layer 50 may include at least an electron blocking layer 51. The electron blocking layer 51 may be disposed adjacent to the light-emitting layer 20.

In one embodiment, as shown in FIG. 4, the electron blocking layer 51 may be disposed between the light-emitting layer 20 and the second electrode 40. Thus, the excessive electrons may be prevented from passing through the light-emitting layer 20 to reach the second electrode 40. The electrons may be effectively confined inside the light-emitting layer 20. The excitons may be prevented from being diffused to other regions outside of the light-emitting layer 20. The exciton yield may be increased. The light-emitting efficiency of the device may be increased, accordingly.

Because the electrons and holes in the OLED device are often not balanced, for the electron-rich device, the electron and hole recombination may occur on the side of the light-emitting layer 20 close to the second electrode 40. As a result, the electrons and holes may be recombined in a narrow region. Under a high current density, the narrow region may have a substantially high exciton density. The excitons may interact with each other, causing triplet-triplet annihilation, and triplet-singlet annihilation, which, in turn, may reduce the exciton utilization rate. Thus, the efficiency of the OLED display panel may be decreased. At the same time, a large number of excitons accumulated in the narrow region may cause the material of the light-emitting layer to deteriorate, reducing the life span of the organic light-emitting display device.

In addition, in one embodiment, the electron blocking layer 51 may be doped with a first guest material D. In the electron blocking layer 51, the ratio of the hole mobility (μₕ_E) corresponding to the host material E over the hole mobility (μₕ_D) corresponding to the first guest material D may be configured to be greater than or equal to about 10. That is, the electron blocking layer 51 may be doped with the first guest material D having a smaller hole mobility (μₕ_D) than the host material E. Thus, the hole movement may be reduced, the balance of the electrons and holes in the device may be adjusted, the electron and hole recombination may be confined in the light-emitting layer 20, and the light-emitting efficiency and the life span of the OLED display panel may be increased.

In one embodiment, as shown in FIG. 4, the first electrode 10 may be a cathode, and the second electrode 40 may be an anode. Optionally, the first function layer 50 may also include at least one of a hole injection layer 53, and a hole transport layer 52. The hole transport layer 52 may be disposed between the electron blocking layer 51 and the hole injection layer 53, and the hole injection layer 53 may be disposed between the hole transport layer 52 and the second electrode 40.

The electron blocking layer 51 may include a hole transport type material. For example, the electron blocking layer 51 may include at least one of a carbazole type electron blocking material, and a triphenylamine type electron blocking material.

The host material E of the electron blocking layer 51 may include, for example, at least one of 4,4′-cyclohexylbis[N,N-bis(4-methylphenyl)aniline] (TAPC), and N,N′-bis-(3-methylphenyl)-N,N′-diphenyl-[1,1′-biphenyl]-4,4′-diamine (TPD). The first guest material D of the electron blocking layer 51 may include, for example, at least one of N,N′-dicarbazolyl-3,5-benzene (mCP), 4,4′,4″-triscarbazolyl-triphenylamine (TCTA), and N,N′-bis(4-fluorophenyl)-N,N′-bis(3-methylphenyl)-9,9′-dimethylfluorence-2,7-diamine (X).

In one embodiment, the lowest unoccupied orbital level LUMO_{E} of the host material E of the electron blocking layer 51 may be at least approximately 0.3 eV higher than the lowest unoccupied orbital level LUMO_{C} of the host material C of the light-emitting layer 20, and the lowest unoccupied orbital level LUMO_{D} of the first guest material D of the electron blocking layer 51 may be at least approximately 0.3 eV higher than the lowest unoccupied orbital level LUMO_{C} of the host material C of the light-emitting layer 20, such that the electron blocking layer 51 may be effective in blocking the electron movement.

Similarly, the utilization rate of the triplet state excitons may be increased from the device structure perspective. After the triplet state excitons are generated in the light-emitting layer 20, through utilizing the higher triplet state energy level property of the hole blocking layer 31, the triplet state excitons in the light-emitting layer 20 may be prevented from being transported to other layers (e.g., the hole transport layer 52) outside the light-emitting layer 20. Thus, the exciton utilization rate of the device may be improved, and the light-emitting efficiency of the device may be increased.

The content of the host material E in the electron blocking layer 51 may be determined according to various application scenarios. In one embodiment, the content (i.e., weight percentage) of the host material E in the electron blocking layer 51 may be configured to be greater than or equal to about 90%. Provided that the content of the host material E effectively confine the electrons in the light-emitting layer 20, through doping the first guest material D into the host material E of the electron blocking layer 51, the hole injection rate into the light-emitting layer 20 may be reduced, and the electrons and holes in the light-emitting layer 20 may be balanced, such that the electrons and holes may be recombined in the center of the light-emitting layer 20. The exciton binding region may be widened, and the efficiency and life span of the device may be increased.

In one embodiment, the hole mobility of the host material E and the first guest material D in the electron blocking layer 51 may be configured to be 10⁻⁴ cm⁻²/V·S≤μₕ_E≤10⁻³ cm⁻²/V·S, and

$${μ}_{h \_} D \leq \frac{{10}^{- 4} {cm}^{- 2}}{V} \cdot S ,$$

respectively. The host material E and the first guest material D may be selected to satisfy the above relationship such that the efficiency and life span of the device may be increased.

For example, μₕ_E may be approximately 10⁻³ cm⁻²/V·S, and μₕ_D may be approximately 10⁻⁴ cm⁻²/V·S. The electron blocking layer 51 may have a thickness ranging approximately between the 1 nm and 20 nm. For example, the hole blocking layer 51 may have a thickness of about 5 nm. The thickness of the electron blocking layer 51 may be selected according to various application scenarios. The electron blocking layer 51 having a substantially thin thickness may be ineffective to block the electron movement, and the electron blocking layer 51 having a substantially thick thickness may not only block the electron movement, but also increase the operating voltage of the device.

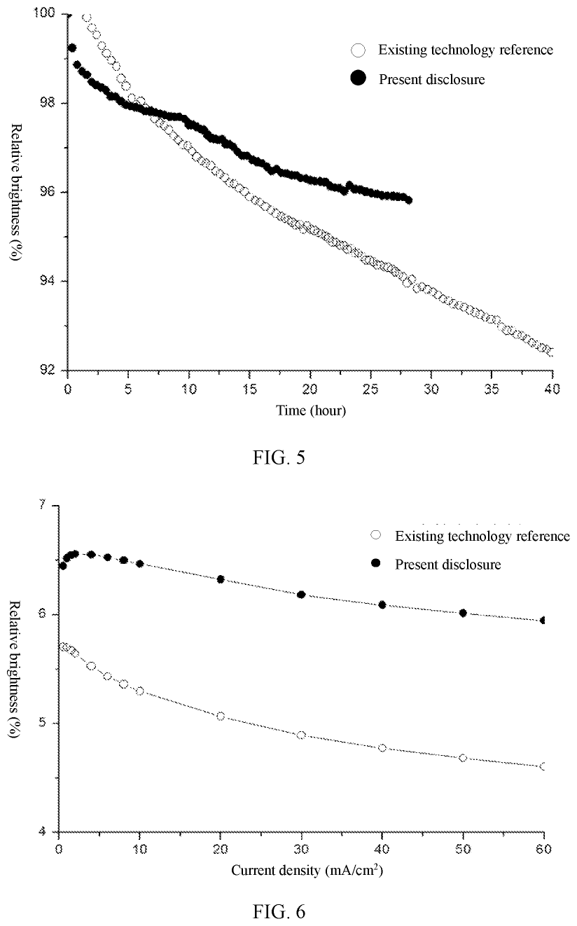

FIG. 5 illustrates a life span measurement result chart comparing an existing OLED display panel and an exemplary hole-rich OLED display panel according to the present disclosure. The device of the existing technology reference 1 in FIG. 5 may include a first electrode, a hole injection layer, a hole transport layer, a light-emitting layer, an electron transport layer, an electron injection layer, and a second electrode.

The first electrode of the existing technology reference 1 may be made of indium tin oxide (ITO), and may have a thickness of about 150 nm. The hole injection layer may be made of N,N-diphenyl-N,N-bis(1-naphthyl)-1,1-diphenyl-4,4-diamine (NPB) doped with 2,3,5,6-tetrafluoro-7,7′,8,8′-tetracyanoquinodimethane (F4-TCNQ). The F4-TCNQ material may have a doping ratio of about 3% by weight. The hole injection layer may have a thickness of about 10 nm. The hole transport layer may be made of NPB, and may have a thickness of about 50 nm.

The host material of the light-emitting layer may be 4,4′-bis(9-carbazole)biphenyl (CBP). The guest material may be tris(2-phenylpyridine) iridium (Ir(PPY)₃). Ir(PPY)₃ may have a doping ratio of about 6% by weight. The light-emitting layer may have a thickness of about 25 nm. The electron transport layer may be made of 8-hydroxyquinoline aluminum (Alq3), and may have a thickness of about 40 nm. The electron injection layer may be made of LiF, and may have a thickness of about 1 nm. The second electrode may be made of Al, and may have a thickness of about 200 nm.

Further, in FIG. 5, the OLED display panel according to the present disclosure may include a first electrode, a hole injection layer, a hole transport layer, an electron blocking layer, a light-emitting layer, a hole blocking layer, an electron transport layer, an electron injection layer, and a second electrode, which are disposed in layers.

In one embodiment, the first electrode may be made of indium tin oxide (ITO), and may have a thickness of about 150 nm. The hole injection layer may be made of N,N-diphenyl-N,N-bis(1-naphthyl)-1,1-diphenyl-4,4-diamine (NPB) doped with 2,3,5,6-tetrafluoro-7,7′,8,8′-tetracyanoquinodimethane (F4-TCNQ). The F4-TCNQ material may have a doping ratio of about 3% by weight. The hole injection layer may have a thickness of about 10 nm. The hole transport layer may be made of NPB, and may have a thickness of about 50 nm.

The host material of the electron blocking layer may be 4,4′-cyclohexylbis[N,N-bis(4-methylphenyl)aniline] (TAPC), and the guest material may be N,N′-bis(4-fluorophenyl)-N,N′-bis(3-methylphenyl)-9,9′-dimethylfluorence-2,7-diamine (X). The X material may have a doping ratio of about 10% by weight. The ratio of the hole mobility of TAPC over the hole mobility of X may be equal to about 27. The electron blocking layer may have a thickness of about 5 nm.

The host material of the light-emitting layer may be 4,4′-bis(9-carbazole)biphenyl (CBP), and the guest material may be tris(2-phenylpyridine) iridium (Ir(PPY)₃). Ir(PPY)₃ may have a doping ratio of about 6% by weight. The light-emitting layer may have a thickness of about 25 nm. The hole blocking layer may be made of 3,3′-[5′-[3-(3-pyridinyl)phenyl][1,1′:3′,1″-terpheny1]-3,3″-diy1]bispyridine (TmPyPB), and may have a thickness of about 5 nm. The electron transport layer may be made of 8-hydroxyquinoline aluminum (Alq3), and may have a thickness of about 40 nm. The electron injection layer may be made of LiF, and may have a thickness of about 1 nm. The second electrode may be made of Al, and may have a thickness of about 200 nm.

The skeletal structural formula of 4,4′-bis(9-carbazole)biphenyl (CBP) forming the light-emitting layer is

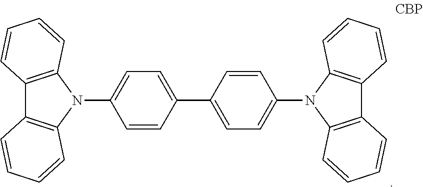 [SMILES: c1ccc2c(c1)c1ccccc1n2-c1ccc(-c2ccc(-n3c4ccccc4c4ccccc43)cc2)cc1 ; "."]

The skeletal structural formula of 3,3′-[5′-[3-(3-pyridinyl)phenyl][1,1′:3′,1″-terpheny1]-3,3″-diy1]bispyridine (TmPyPB) forming the hole blocking layer is

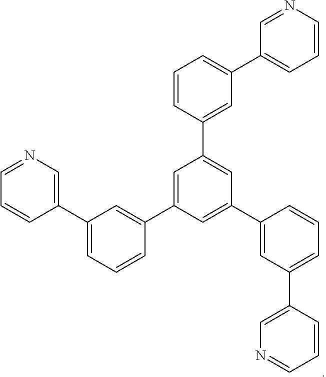 [SMILES: c1cncc(-c2cccc(-c3cc(-c4cccc(-c5cccnc5)c4)cc(-c4cccc(-c5cccnc5)c4)c3)c2)c1 ; "."]

The skeletal structural formula of N,N′-bis(4-fluorophenyl)-N,N′-bis(3-methylphenyl)-9,9′-dimethylfluorence-2,7-diamine (X) forming the electron blocking layer is

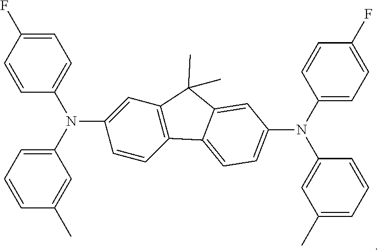 [SMILES: Cc1cccc(N(c2ccc(F)cc2)c2ccc3c(c2)C(C)(C)c2cc(N(c4ccc(F)cc4)c4cccc(C)c4)ccc2-3)c1 ; "."]

The skeletal structural formula of N,N′-bis-(3-methylphenyl)-N,N′-diphenyl-[1,1′-biphenyl]-4,4′-diamine (TPD) forming the electron blocking layer is

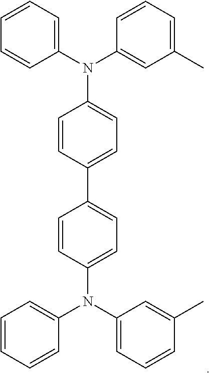 [SMILES: Cc1cccc(N(c2ccccc2)c2ccc(-c3ccc(N(c4ccccc4)c4cccc(C)c4)cc3)cc2)c1 ; "."]

The skeletal structural formula of N,N′-dicarbazolyl-3,5-benzene (mCP) forming the electron blocking layer is

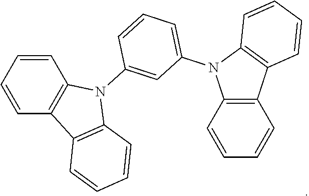 [SMILES: c1cc(-n2c3ccccc3c3ccccc32)cc(-n2c3ccccc3c3ccccc32)c1 ; "."]

The skeletal structural formula of 4,4′,4″-triscarbazolyl-triphenylamine (TCTA) forming the electron blocking layer is

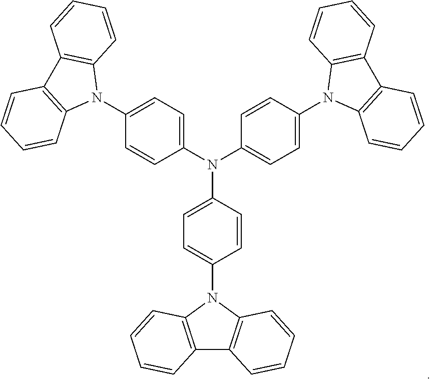 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; "."]

Other organic function materials may have the skeletal structural formula as previously described.

Referring to FIG. 5, the OLED display panel disclosed by the present disclosure and the existing technology reference 1 may be tested under the current density of about 50 mA/cm². In FIG. 5, the abscissa denotes may be time (unit: hour), and the ordinate denotes the relative luminance. As shown in FIG. 5, the relative luminance of the OLED display panel disclosed by the present disclosure may be attenuated slower than the relative luminance of the existing technology reference 1. After about 15 hours, the relative luminance of the existing technology reference 1 may be attenuated to about 95.9% while the relative luminance of the OLED display panel disclosed by the present disclosure may be attenuated to about 96.8%.

As shown in FIG. 5, the curve corresponding to the OLED display panel disclosed by the present disclosure may have a flatter slope. That is, the relative luminance of the OLED display panel disclosed by the present disclosure may be attenuated in a slower pace. Thus, the disclosed OLED display panel may have a longer life span than the existing technology reference 1.

In one embodiment, an electron blocking layer and a hole blocking layer may be configured on both sides of the light-emitting layer, respectively, to avoid excessive number of electrons and holes passing through the light-emitting layer. In addition, a guest material having a smaller hole mobility than the host material may be doped into the electron blocking layer. For the hole-rich OLED device, the electron movement may be reduced, the balance of the electrons and holes in the light-emitting layer may be adjusted, and the electron and hole recombination may be confined inside the light-emitting layer. Accordingly, the efficiency of the organic electroluminescent device may be further improved.

Thus, the disclosed OLED display panel may be operated at a relatively low operating voltage, leading to a slower attenuation of the relative luminance, and a longer device life span. In addition, in the disclosed OLED display panel, the electron movement and the hole movement may be further balanced, the material deterioration may be suppressed, and the life span may be extended.

FIG. 6 illustrates a current density vs external quantum efficiency measurement result chart comparing an existing OLED display panel and an exemplary display panel shown in FIG. 5. As shown in FIG. 6, given a same current density, the OLED display panel according to the present disclosure may have a substantially higher external quantum efficiency than the existing technology reference 1.

Because the OLED display panel according to the present disclosure may have the electron blocking layer and the hole blocking layer disposed on both sides of the light-emitting layer, respectively, excessive electrons and holes may be prevented from passing through the light-emitting layer. Thus, the energy of the electrons and holes may be fully unitized to stimulate the light emitting in the light-emitting material. Accordingly, the reduction of the efficiency and life span of the OLED display panel, which is caused by the insufficient usage of the energy of the electrons and holes, may be prevented.

In addition, in one embodiment, for the hole-rich device, because the electron blocking layer is doped with a guest material having a smaller hole mobility than the host material, the hole movement may be reduced, and the balance of the electrons and holes in the OLED display panel may be adjusted. Thus, the external quantum efficiency of the disclosed OLED display panel may be greater than the external quantum efficiency of the existing technology reference 1.

In the disclosed embodiments, an electron blocking layer and a hole blocking layer may be disposed on both sides of the light-emitting layer, respectively. The electron blocking layer may be configured to block an excessive number of the electrons from transporting to the hole transport layer. The hole blocking layer may be configured to block an excessive number of the holes from transporting to the electron transport layer. Certain examples are shown in FIG. 2, FIG. 3, FIG. 5, and FIG. 6.

The OLED display panels shown in FIG. 2 and FIG. 3 may be applicable to the electron-rich devices, in which a guest material having a smaller electron mobility than the host material may be doped into the hole blocking layer to reduce the electron movement. The OLED display panels shown in FIG. 5 and FIG. 6 may be applicable to the hole-rich devices, in which a guest material having a smaller hole mobility than the host material may be doped into the electron blocking layer to reduce the hole movement.

In certain embodiments, either an electron blocking layer or a hole blocking layer may be configured on only one side of the light-emitting layer, and the electron blocking layer or the hole blocking layer may be doped with a guest material having a desired carrier mobility. Certain examples are shown in FIG. 1 and FIG. 4. In practical applications, the OLED display panel may be specifically designed according to various application scenarios, and is not limited by the present disclosure.

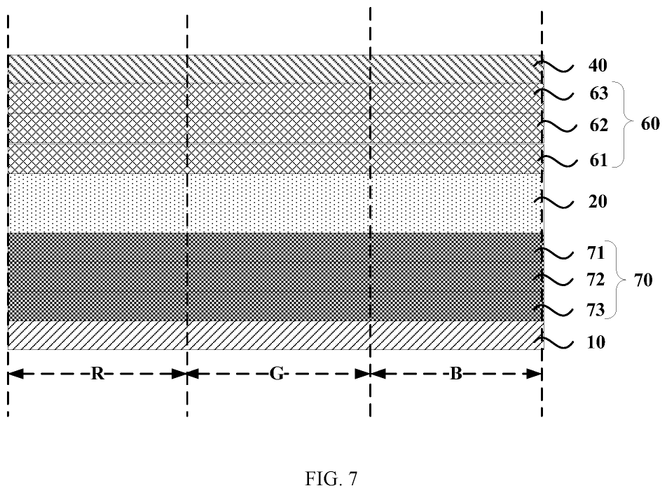

FIG. 7 illustrates a cross-sectional view of another exemplary OLED display panel according to the present disclosure. As shown in FIG. 7, the OLED display panel may include at least a first electrode 10, a second function layer 70, a light-emitting layer 20, a first function layer 60, and a second electrode 40, which are disposed in layers or a stacked configuration. The first function layer 60 may include at least a hole blocking layer 61. The hole blocking layer 61 may be disposed adjacent to the light-emitting layer 20. The second function layer 70 may include at least an electron blocking layer 71. The electrode blocking layer 71 may be disposed adjacent to the light-emitting layer 20.

In particular, the hole blocking later 61 may be disposed between the light-emitting layer 20 and the second electrode 40, such that an excessive number of holes may be prevented from passing through the light-emitting layer 20 to reach the second electrode 40, and the holes may be effectively confined in the light-emitting layer 20. The electron blocking layer 71 may be disposed between the light-emitting layer 20 and the first electrode 10, such that excessive electrodes may be prevented from passing through the light-emitting layer 20 to reach the first electrode 10, and the electrons may be effectively confined in the light-emitting layer 20. Thus, the exciton yield may be increased, and the light-emitting efficiency of the OLED display panel may be increased.

In one embodiment, the hole blocking layer 61 may be doped with a first guest material A. In the hole blocking layer 61, the ratio of the electron mobility μₑ_B corresponding to the host material B over the electron mobility μₑ_A corresponding to the first guest material A may be configured to be greater than or equal to about 10. That is, the hole blocking layer 61 may be doped with the first guest material A having a smaller electron mobility μₑ_A than the host material B. Thus, the electron movement may be reduced, the rate of the electron injection into the light-emitting layer 20 may be reduced, and the exciton binding region may be moved away from the interface of the light-emitting layer 20 adjacent to the first electrode 10.

In one embodiment, the electron blocking layer 71 may be doped with a second guest material D. In the electron blocking layer 71, the ratio of the hole mobility μₕ_E corresponding to the host material E over the hole mobility μₕ_D corresponding to the second guest material D may be configured to be greater than or equal to about 10. That is, the electron blocking layer 71 may be doped with the second guest material D having a smaller hole mobility μₕ_D than the host material E. Thus, the hole movement may be reduced, the rate of the hole injection into the light-emitting layer 20 may be reduced, and the exciton binding region may be moved away from the interface of the light-emitting layer 20 adjacent to the second electrode 40.

Thus, in the disclosed OLED display panel, a portion of the excitons formed by the electron and hole recombination may be prevented from diffusing toward both sides of the light-emitting layer 20, the balance of the electrons and holes in the light-emitting layer 20 may be adjusted, the electron and hole recombination may occur in the center of the light-emitting layer 20, the exciton binding region may be widened, and the efficiency and the life span of the OLED display panel may be improved.

In addition, in one embodiment, the highest occupied orbital level HOMO_{B} of the host material B of the hole blocking layer 61 may be at least approximately 0.3 eV higher than the highest occupied orbital level HOMO_{C} of the host material C of the light-emitting layer 20, and the highest occupied orbital level HOMO_{A} of the first guest material A of the hole blocking layer 61 may be at least approximately 0.3 eV higher than the highest occupied orbital level HOMO_{C} of the host material C of the light-emitting layer 20, such that the hole blocking layer 61 may be effective in blocking hole movement.

The triplet state energy level T_{B} of the host material B of the hole blocking layer 61 may be configured to be greater than the triplet state energy level T_{C} of the host material C of the light-emitting layer 20, and the triplet state energy level T_{A} of the first guest material A of the hole blocking layer 61 may be configured to be greater than the triplet state energy level T_{C} of the host material C of the light-emitting layer 20, which may improve the utilization rate of the triplet state excitons from the device structure perspective.

At the same time, the highest occupied orbital level HOMO_{E} of the host material E of the electron blocking layer 71 may be at least approximately 0.3 eV higher than the highest occupied orbital level HOMO_{C} of the host material C of the light-emitting layer 20, and the highest occupied orbital level HOMO_{D} of the second guest material D of the electron blocking layer 71 may be at least approximately 0.3 eV higher than the highest occupied orbital level HOMO_{C} of the host material C of the light-emitting layer 20, such that the electron blocking layer 71 may be effective in blocking electron movement.

Similarly, the utilization rate of the triplet state excitons may be improved from the device structure perspective. After the triplet state excitons are generated in the light-emitting layer 20, through utilizing the higher triplet state energy level property of the electron blocking layer 71, the triplet state excitons in the light-emitting layer 20 may be prevented from being transported to other layers (e.g., the hole transport layer 52) outside the light-emitting layer 20. Thus, the exciton utilization rate of the device may be improved, and the light-emitting efficiency of the device may be increased.

The content of the host material B in the hole blocking layer 61 may be configured to be greater than or equal to about 90%. The content of the host material E in the electron blocking layer 71 may be configured to be greater than or equal to about 90%.

In one embodiment, the electron mobility μₑ_B of the host material B in the hole blocking layer 61 may be configured to be greater than or equal to about 10⁻⁴ cm⁻²/V·S, and less than or equal to 10⁻³ cm⁻²/V·S. The electron mobility μₑ_A of the first guest material A in the hole blocking layer 61 may be configured to be less than or equal to about 10⁻⁴ cm⁻²/V·S. The hole mobility μₕ_E of the host material E in the electron blocking layer 71 may be configured to be greater than or equal to about 10⁻⁴ cm⁻²/V·S, and less than or equal to 10⁻³ cm⁻²/V·S. The hole mobility μₕ_D of the second guest material D in the electron blocking layer 71 may be configured to be less than or equal to about 10⁻⁴ cm⁻²/V·S. The hole blocking layer 61 may have a thickness ranging approximately between 1 nm and 20 nm. The electron blocking layer 71 may have a thickness ranging approximately between 1 nm and 20 nm.

Optionally, the first function layer 60 may also include at least one of an electron injection layer 63, and an electron transport layer 62. Referring to FIG. 7, the electron transport layer 62 may be disposed between the hole blocking layer 61 and the electron injection layer 63, and the electron injection layer 63 may be disposed between the electron transport layer 62 and the second electrode 40. Optionally, the second function layer 70 may also include at least one of a hole injection layer 73 and a hole transport layer 72. Referring to FIG. 7, the hole transport layer 72 may be disposed between the electron blocking layer 71 and the hole injection layer 73, and the hole injection layer 73 may be disposed between the hole transport layer 72 and the first electrode 10.

In one embodiment, the OLED display panel disclosed by the present disclosure may include a plurality of pixel regions emitting light of different colors. For example, in FIG. 1, FIG. 4, and FIG. 7, a red light-emitting pixel region R, a green light-emitting pixel region G, and a blue light-emitting pixel region B are illustrated. The number and the colors of the light-emitting pixel regions are for illustrative purposes and are not intended to limit the scope of the present disclosure.

In one embodiment, the light-emitting layer 20 may include a host material and a guest material. At least one of the light-emitting layer 20 corresponding to the red light-emitting pixel region R and the light-emitting layer 20 corresponding to the blue light-emitting pixel region B may be made of one or two host materials. The light-emitting layer 20 corresponding to the green light-emitting pixel region G may be made of at least two host materials.

In the light-emitting layer 20, the host material content may be more than the guest material content. Generally, the absolute value of a HOMO energy level |Tₕₒₛₜ(HOMO)| of the host material may be greater than the absolute value of a HOMO energy level |T_{dopant}(HOMO)| of the guest material, the absolute value of a LUMO energy level |Tₕₒₛₜ(LUMO)| of the host material may be smaller than the absolute value of a LUMO energy level |T_{dopant}(LUMO)| of the guest material, and a triplet state energy level Tₕₒₛₜ(S) of the host material may be greater than a triplet state energy level T_{dopant}(S) of the guest material. The triplet state energy of the host material may be effectively transferred to the guest material, and the light emission spectrum of the host material may match the light absorption spectrum of the guest material.

In addition, the guest material of the light-emitting layer 20 may include a phosphorescent or fluorescent material. For example, the guest material of the light-emitting layer 20 corresponding to the red light-emitting pixel region R and the green light-emitting pixel region G may be a phosphorescent material, and the guest material of the light-emitting layer 20 corresponding to the blue light-emitting pixel region B may be a fluorescent material. The material of the light-emitting layer 20 is not limited by the present disclosure. For example, the light-emitting layer 20 may be made of a material other than the host-guest dopant structure or made of a thermally activated delayed fluorescent (TADF) material.

In certain embodiments, a micro-cavity structure may be formed between a first electrode and a second electrode of a pixel region in the OLED display panel. The cavity length of the micro-cavity structure corresponding to the pixel region may be positively correlated with the wavelength of the emission color corresponding to the pixel region. The cavity length of the micro-cavity structure may be a distance between the first electrode and the second electrode of the pixel region. The micro-cavity structure may confine the light in a substantially small wavelength band by effects of reflection, total reflection, interference, diffraction, and scattering on the discontinuous interfaces of refractive index.

By designing the cavity length and the thickness of each layer in the micro-cavity structure, the wavelength center of the emission light may be located near an enhancement peak of the standing wave field, which may increase a coupling efficiency between a radiation dipole and an electric field in the cavity, thereby improving the light-emitting efficiency and brightness of the OLED display panel. The cavity length of the micro-cavity structure may be adjusted by adjusting the thicknesses of individual layers of the first function layer, the thickness of the light-emitting layer, and the thicknesses of individual layers of the second function layer.

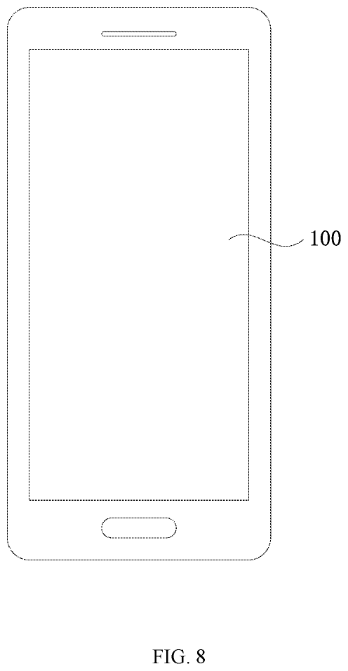

The present disclosure also provides an electronic device. FIG. 8 illustrates a schematic view of an exemplary electronic device according to the present disclosure. As shown in FIG. 8, the electronic device may include any one of the disclosed OLED display panels 100. The electronic device may be a smart phone as shown in FIG. 8, a computer, a television set, or a smart wearable device, etc., which is not limited by the present disclosure.

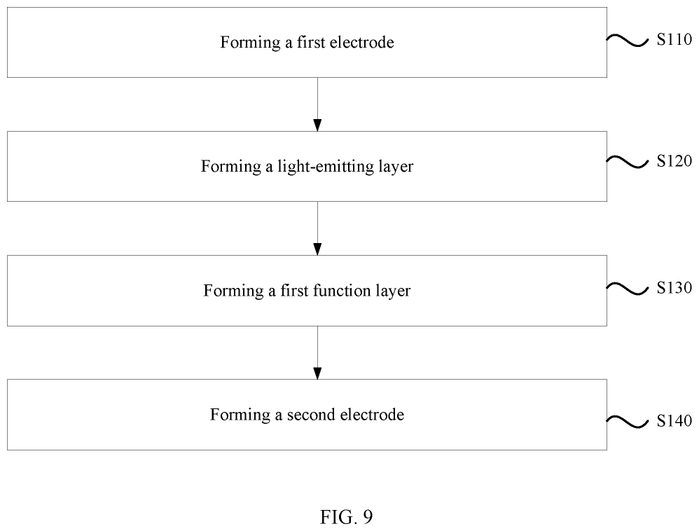

The present disclosure also provides a manufacturing method for the OLED display panel. FIG. 9 illustrates a flow chart of an exemplary manufacturing method for an exemplary OLED display panel according to the present disclosure. As shown in FIG. 9, at the beginning, a first electrode is formed on a substrate (S110). The corresponding structure is shown in FIG. 1 and FIG. 4.

For example, the first electrode 10 may be a reflective electrode made of a metal alloy containing Ag or Mg, or a transparent electrode made of indium tin oxide or indium zinc oxide.

In certain embodiments, after the first electrode 10 is formed, a pixel defining layer (not shown in FIGS. 1 and 4) may also be formed. The pixel defining layer may include a plurality of opening structures. Each opening structure may correspond to a pixel region.

In certain other embodiments, before the first electrode 10 is formed, a pixel defining layer may be formed. The pixel defining layer may include a plurality of opening structures. Then, the first electrode 10 may be formed in each opening structure. The pixel defining layer may prevent undesired color mixing in the subsequently formed light-emitting layer 20.

Returning to FIG. 9, after the first electrode is formed, a light-emitting layer is formed on the first electrode (S120). The corresponding structure is shown in FIG. 1 and FIG. 4.

For the light-emitting regions of different emission colors, the light-emitting layer 20 may be sequentially deposited by using masks. In certain embodiments, the thicknesses of the light-emitting layers corresponding to the light-emitting regions of different emission colors may be the same. In certain other embodiments, the thicknesses of the light-emitting layers 20 corresponding to the light-emitting regions of different emission colors may be different.

The thicknesses of the light-emitting layers 20 corresponding to the light-emitting regions of different emission colors may be determined according to various factors, such as the actual manufacturing requirements, the micro-cavity structures corresponding to the light-emitting regions of different emission colors, light-emitting layer characteristics, and the transport balances between holes and electrons in different light-emitting regions, etc., as long as through adjusting the cavity lengths of the corresponding micro-cavity structures, the light emitted from the light-emitting layers 20 corresponding to the light-emitting regions of different emission colors may be enhanced by the constructive interference, i.e. the brightness may be increased.

Returning to FIG. 9, after the light-emitting layer is formed on the first electrode, a first function layer is formed on the light-emitting layer (S130). The corresponding structure is shown in FIG. 1 and FIG. 4.

As shown in FIG. 1 and FIG. 4, the first function layers 30 and 50 may include at least a first-type blocking layer. The first-type blocking layer may be disposed adjacent to the light-emitting layer 20. A first guest material may be doped in the first-type blocking layer. The ratio of the second-type carrier mobility of the host material of the first-type blocking layer over the second-type carrier mobility of the first guest material may be configured to be greater than or equal to about 10. In one embodiment, the first-type may be a hole-type, and the second-type may be an electron-type. In another embodiment, the first-type may be an electron-type, and the second-type may be a hole-type.

Returning to FIG. 9, after the first function layer is formed on the light-emitting layer, a second electrode is formed on the first function layer (S140). The corresponding structure is shown in FIG. 1 and FIG. 4.

For example, the second electrode 40 may be made of a metal, such as Ag, or made of a transparent metal oxide, such as indium tin oxide.

In certain embodiments, a first-type blocking layer may be formed between the light-emitting layer 20 and the second electrode 40, such that an excessive number of first-type carriers may be prevented from passing through the light-emitting layer 20 to reach the side of the light-emitting layer 20 facing away from the first electrode 10. The first-type blocking layer may prevent the excitons from diffusing into layers other than the light-emitting layer 20, thereby increasing the exciton yield and the light-emitting efficiency of the OLED display panel.

In addition, a guest material may be doped in the first-type blocking layer, in which the ratio of the second-type carrier mobility of the host material over the second-type carrier mobility of the first guest material may be configured to be greater than or equal to about 10. That is, a guest material having a smaller second-type carrier mobility than the host material may be doped in the first-type blocking layer. For second-type-carrier-rich devices, the guest material may reduce the movement of the second-type carriers, and may move the exciton recombination region away from the interface of the light-emitting layer 20 adjacent to the first electrode 10. Thus, the excitons formed by the electron and hole recombination may be prevented from diffusing to both sides of the light-emitting layer, and the efficiency of the OLED display panel may be improved.

In certain other embodiments, the OLED display panel may be formed by sequentially forming a second electrode 40, a first function layer 30 and 50, a light-emitting layer 20, and a first electrode 10.

In the disclosed embodiments, when the first electrode 10 in the OLED display panel is an anode, the second electrode 40 is a cathode, the first-type is a hole-type, and the second-type is an electron-type, the following conditions may be satisfied: T_{B}>T_{C}, T_{A}>T_{C}, HOMO_{B}−HOMO_{C}≥0.3 eV, and HOMO_{A}−HOMO_{C}≥0.3 eV, where T_{B} is the triplet state energy level of the host material B of the first-type blocking layer, T_{C} is the triplet state energy level of the host material C of the light-emitting layer 20, T_{A} is the triplet state energy level of the first guest material A of the first-type blocking layer, HOMO_{B} is the highest occupied molecular orbital energy level of the host material B of the first-type blocking layer, HOMO_{C} is the highest occupied molecular orbital energy level of the host material C of the light-emitting layer 20, and HOMO_{A} is the highest occupied molecular orbital energy level of the first guest material A of the first-type blocking layer.

Both the host material B and the first guest material A in the hole blocking layer have a higher triplet state energy level than the host material C in the light-emitting layer 20, such that the excitons formed by the electron and hole recombination may be prevented from diffusing to organic layers other than the light-emitting layer 20 and, accordingly, the efficiency of the OLED device may be improved.

In certain embodiments, when the first-type is a hole-type, and the second-type is an electron-type, the host material B of the first-type blocking layer may include at least one of 3,3′-[5′-[3-(3-pyridinyl)phenyl][1,1′:3′,1″-terpheny1]-3,3″-diy1]bispyridine (TmPyPB), 4,4-bis(9-carbazolyl)-1,1′-biphenyl (BCP), 4,6-bis(3,5-di(pyridine-4-yl)phenyl)-2-MethylpyriMidine (B4PyMPM), star oxadiazole, and 1,3,5-tris(N-phenyl-2-benzimidazole) benzene (TPBi). The first guest material A of the first-type blocking layer may include at least one of 8-hydroxyquinoline aluminum (Alq3), 8-hydroxyquinoline lithium (Liq), 2-(4-biphenyl)-5-phenyl oxadiazole (PBD), 2,5-bis-(4-naphthyl)-1,3,4-oxadiazole (BND), tris-(2,3,5,6-trimethyl)phenylboron, and 2,5-diaryl silicon.

In the disclosed embodiments, when the first electrode 10 is a cathode, the second electrode 40 is an anode, the first-type is an electron-type, and the second-type is a hole-type, the following conditions may be configured: T_{E}>T_{C}, T_{D}>T_{C}, LUMO_{E}−LUMO_{C}≥0.3 eV, and LUMO_{D}−LUMO_{C}≥0.3 eV. T_{E} is the triplet state energy level of the host material E of the first-type blocking layer, T_{C} is the triplet state energy level of the host material C of the light-emitting layer 20, T_{D} is the triplet state energy level of the first guest material D of the first-type blocking layer, HOMO_{E} is the highest occupied molecular orbital energy level of the host material E of the first-type blocking layer, HOMO_{C} is the highest occupied molecular orbital energy level of the host material C of the light-emitting layer 20, and HOMO_{D} is the highest occupied molecular orbital energy level of the first guest material D of the first-type blocking layer.

Both the host material E and the first guest material D in the hole blocking layer have a higher triplet state energy level than the material C in the light-emitting layer 20, such that a portion of the excitons formed by the electron and hole recombination may be prevented from diffusing to organic layers other than the light-emitting layer 20, which is desired for improving the efficiency of the OLED device.

In certain other embodiments, when the first-type is an electron-type, and the second-type is a hole-type, the host material E of the first-type blocking layer may include at least one of 4,4′-cyclohexylbis[N,N-bis(4-methylphenyl)aniline] (TAPC), and N,N′-bis-(3-methylphenyl)-N,N′-diphenyl-[1,1′-biphenyl]-4,4′-diamine (TPD). The first guest material D of the first-type blocking layer may include at least one of N,N′-dicarbazolyl-3,5-benzene (mCP), 4,4′,4″-triscarbazolyl-triphenylamine (TCTA), and N,N′-bis(4-fluorophenyl)-N,N′-bis(3-methylphenyl)-9,9′-dimethylfluorence-2,7-diamine (X).

In certain embodiments, as shown in FIG. 7, after the first electrode 10 is formed and before the light-emitting layer 20 is formed, or after the light-emitting layer 20 is formed and before the first electrode 10 is formed, the disclosed manufacturing method may also include forming a second function layer 70. The second function layer 70 may include at least a second-type blocking layer. The second blocking layer may be disposed adjacent to the light-emitting layer 20.

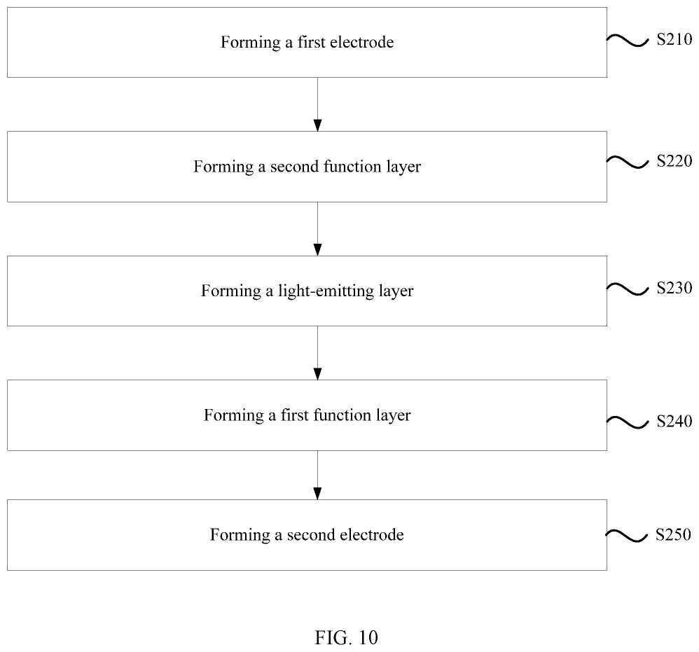

Further, a second guest material may be doped in the second-type blocking layer, in which the ratio of the first-type carrier mobility of the host material over the first-type carrier mobility of the second guest material may be configured to be greater than or equal to about 10. Thus, the balance of the electron and hole movement in the OLED display panel may be improved, the carrier recombination region may be confined near to the light-emitting layer 20, the excitons formed by the electron and hole recombination may be prevented from diffusing toward both sides of the light-emitting layer 20, and the efficiency of the OLED device may be increased. A flow chart of a corresponding manufacturing method is shown in FIG. 10.

FIG. 10 illustrates a flow chart of another exemplary method for manufacturing an exemplary OLED display panel according to the present disclosure. As shown in FIG. 10, at the beginning, a first electrode is formed on a substrate (S210). The corresponding structure is shown in FIG. 7.

A shown in FIG. 7, the first electrode 10 may be a reflective electrode made of, for example, a metal alloy containing Ag or Mg, or a transparent electrode made of, for example, indium tin oxide or indium zinc oxide.

In certain embodiments, after the first electrode 10 is formed, a pixel defining layer (not shown in FIG. 7) may also be formed. The pixel defining layer may include a plurality of opening structures. Each opening structure may correspond to a pixel region.

In certain other embodiments, before the first electrode 10 is formed, a pixel defining layer (not shown in FIG. 7) may be formed. The pixel defining layer may include a plurality of opening structures. Then, a first electrode 10 may be formed in each opening structure. The pixel defining layer may prevent undesired color mixing of the subsequently formed light-emitting layer 20.

Returning to FIG. 10, after the first electrode is formed, a second function layer is formed on the first electrode (S220). The corresponding structure is shown in FIG. 7.

A shown in FIG. 7, the second function layer 70 may include at least a second-type blocking layer. The second-type blocking layer may be disposed adjacent to the light-emitting layer 20. A second guest material may be doped in the second-type blocking layer. In the second-type blocking layer, the ratio of a first-type carrier mobility of the host material over the first-type carrier mobility of the second guest material may be configured to be greater than or equal to about 10. In one embodiment, the first-type may be a hole-type, and the second-type may be an electron-type. In another embodiment, the first-type may be an electron-type, and the second-type may be a hole-type.

Returning to FIG. 10, after the second function layer is formed, a light-emitting layer is formed on the second function layer (S230). The corresponding structure is shown in FIG. 7.

As shown in FIG. 7, for the light-emitting regions of different emission colors, the light-emitting layer 20 may be sequentially deposited by using masks. In certain embodiments, the thicknesses of the light-emitting layers 20 corresponding to the light-emitting regions of different emission colors may be the same. In certain other embodiments, the thicknesses of the light-emitting layers 20 corresponding to the light-emitting regions of different emission colors may be different.

The thicknesses of the light-emitting layers 20 corresponding to the light-emitting regions of different emission colors may be determined according to various factors, such as the actual manufacturing requirements, the micro-cavity structures corresponding to the light-emitting regions of different emission colors, light-emitting layer characteristics, and the transport balances between holes and electrons in different light-emitting regions, etc., as long as, through adjusting the cavity lengths of the corresponding micro-cavity structures, the light emitted from the light-emitting layers 20 corresponding to the light-emitting regions of different emission colors can be enhanced by a constructive interference.

Returning to FIG. 10, after the light-emitting layer is formed on the second function layer, a first function layer is formed on the light-emitting layer (S240). The corresponding structure is shown in FIG. 7.

As shown in FIG. 7, the first function layer 60 may include at least a first-type blocking layer. The first-type blocking layer may be disposed adjacent to the light-emitting layer. A first guest material may be doped in the first-type blocking layer. In the first-type blocking layer, the ratio of a second-type carrier mobility of the host material over the second-type carrier mobility of the first guest material may be configured to be greater than or equal to about 10. In one embodiment, the first-type may be a hole-type, and the second-type may be an electron-type. In another embodiment, the first-type may be an electron-type, and the second-type may be a hole-type.

Returning to FIG. 10, after the first function layer is formed on the light-emitting layer, a second electrode is formed on the first function layer (S250). The corresponding structure is shown in FIG. 7.

As shown in FIG. 7, the second electrode 40 may be made of a metal, such as Ag, or a transparent metal oxide, such as indium tin oxide.

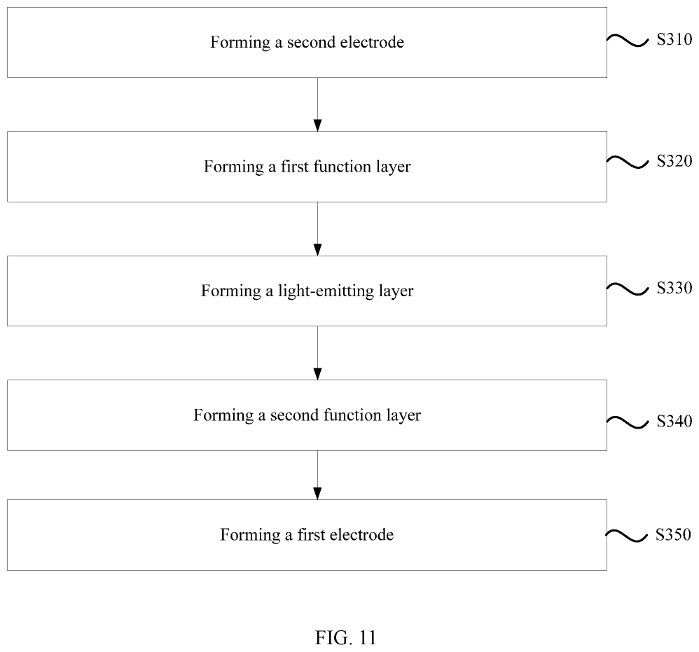

In another embodiment, the second electrode may be formed on the substrate first, then the first function layer, the light-emitting layer, the second function layer and the first electrode may be sequentially formed on the second electrode. A flow chart of the corresponding manufacturing method is shown in FIG. 11.

FIG. 11 illustrates a flow chart of another exemplary manufacturing method for an exemplary OLED display panel according to the present disclosure. As shown in FIG. 11, at the beginning, a second electrode is formed on a substrate (S310). The corresponding structure is shown in FIG. 7.

As shown in FIG. 7, the second electrode 40 may be a reflective electrode made of, for example, a metal alloy containing Ag or Mg, or a transparent electrode made of, for example, indium tin oxide or indium zinc oxide.

In certain embodiments, after the second electrode 40 is formed, a pixel defining layer (not shown in FIG. 7) may also be formed. The pixel defining layer may include a plurality of opening structures. Each opening structure may correspond to a pixel region.

In certain other embodiments, before the second electrode 40 is formed, a pixel defining layer may be formed. The pixel defining layer may include a plurality of opening structures. Then, a second electrode 40 may be formed in each opening structure. The pixel defining layer may prevent undesired color mixing of the subsequently formed light-emitting layer 20.

Returning to FIG. 11, after the second electrode is formed, a first function layer is formed on the second electrode (S320). The corresponding structure is shown in FIG. 7.

As shown in FIG. 7, the first function layer 60 may include at least a first-type blocking layer. The first-type blocking layer may be disposed adjacent to the light-emitting layer 20. A first guest material may be doped in the first-type blocking layer. In the first-type blocking layer, the ratio of a second-type carrier mobility of the host material over the second-type carrier mobility of the first guest material may be configured to be greater than or equal to about 10. In one embodiment, the first-type may be a hole-type, and the second-type may be an electron-type. In another embodiment, the first-type may be an electron-type, and the second-type may be a hole-type.

Returning to FIG. 11, after the first function layer is formed on the second electrode, a light-emitting layer is formed on the first function layer (S330). The corresponding structure is shown in FIG. 7.

As shown in FIG. 7, for the light-emitting regions of different emission colors, the light-emitting layer 20 may be sequentially deposited by using masks. In certain embodiments, the thicknesses of the light-emitting layers 20 corresponding to the light-emitting regions of different emission colors may be the same. In certain other embodiments, the thicknesses of the light-emitting layers 20 corresponding to the light-emitting regions of different emission colors may be different.

The thicknesses of the light-emitting layers 20 corresponding to the light-emitting regions of different emission colors may be determined according to various factors, such as the actual manufacturing requirements, the micro-cavity structures corresponding to the light-emitting regions of different emission colors, light-emitting layer characteristics, and the transport balances between holes and electrons in different light-emitting regions, etc., as long as, through adjusting the cavity lengths of the corresponding micro-cavity structures, the light emitted from the light-emitting layers 20 corresponding to the light-emitting regions of different emission colors can be enhanced by a constructive interference.

Returning to FIG. 11, after the light-emitting layer is formed on the first function layer, a second function layer is formed on the first electrode (S340). The corresponding structure is shown in FIG. 7.

As shown in FIG. 7, the second function layer 70 may include at least a second-type blocking layer. The second-type blocking layer may be disposed adjacent to the light-emitting layer 20. A second guest material may be doped in the second-type blocking layer. In the second-type blocking layer, the ratio of a first-type carrier mobility of the host material over the first-type carrier mobility of the second guest material may be configured to be greater than or equal to about 10. The first-type may be a hole-type, and the second-type may be an electron-type. Alternatively, the first-type may be an electron-type, and the second-type may be a hole-type.

Returning to FIG. 11, after the second function layer is formed on the light-emitting layer, a first electrode is formed on the second function layer (S350). The corresponding structure is shown in FIG. 7.

As shown in FIG. 7, the first electrode 10 may be a reflective electrode made of a metal alloy containing Ag or Mg, or a transparent electrode made of indium tin oxide or indium zinc oxide.

In certain embodiments, the content of the host material in the first-type blocking layer and the second-type blocking layer may be configured to be greater than or equal to about 90%. The first function layer 60 may also include at least one of a first-type injection layer, and a first-type transport layer. The second function layer 70 may also include at least one of a second-type injection layer, and a second-type transport layer. The first-type blocking layer and the second-type blocking layer may have a thickness ranging approximately between 1 nm and 20 nm.

In certain embodiments, the second-type carrier mobility of the host material in the first-type blocking layer may be configured to be greater than or equal to about 10⁻⁴ cm⁻²/V·S, and less than or equal to 10⁻³ cm⁻²/V·S. The second-type carrier mobility of the first guest material in the first-type blocking layer may be configured to be less than or equal to about 10⁻⁴ cm⁻²/V·S. The first-type carrier mobility of the host material in the second-type blocking layer may be configured to be greater than or equal to about 10⁻⁴ cm⁻²/V·S, and less than or equal to 10⁻³ cm⁻²/V·S. The first-type carrier mobility of the second guest material in the second-type blocking layer may be configured to be less than or equal to about 10⁻⁴ cm⁻²/V·S.

In certain embodiments, the first-type blocking layer having a doped structure may be adopted to adjust the carrier balance, confine the exciton recombination region in the light-emitting layer, prevent a portion of the excitons formed by electron and hole recombination from diffusing to other layers on both sides of the light-emitting layer, and increase the efficiency and life span of the OLED device.

As described above, the present disclosure provides an OLED display panel, an electronic device, and a manufacturing method. The disclosed OLED display panel may include at least a first electrode, a light-emitting layer, a first function layer, and a second electrode, which are disposed in stacked layers. The first function layer may include at least a first-type blocking layer. The first-type blocking layer may be disposed adjacent to the light-emitting layer. The first-type blocking layer may be doped with a first guest material.

In the first-type blocking layer, the ratio of the second-type carrier mobility of the host material over the second-type carrier mobility of the first guest material may be configured to be greater than or equal to about 10, thereby improving the light-emitting efficiency and life span of the OLED display panel.

Various embodiments have been described to illustrate the operation principles and exemplary implementations. It should be understood by those skilled in the art that the present invention is not limited to the specific embodiments described herein and that various other obvious changes, rearrangements, and substitutions will occur to those skilled in the art without departing from the scope of the invention. Thus, while the present invention has been described in detail with reference to the above described embodiments, the present invention is not limited to the above described embodiments, but may be embodied in other equivalent forms without departing from the scope of the present invention, which is determined by the appended claims.

What is claimed is:

1. An OLED display panel, comprising:
a first electrode;
a light-emitting layer, the light-emitting layer including a host material of the light-emitting layer and a guest material of the light-emitting layer;
a first function layer including at least a first-type blocking layer disposed adjacent to the light-emitting layer, wherein a first guest material is doped into a host material of the first-type blocking layer, and a ratio of a second-type carrier mobility of the host material over a second-type carrier mobility of the first guest material is greater than or equal to about 10; and
a second electrode,
wherein the first-type is a hole-type and the second-type is an electron-type, and
T_{B}>T_{C} and T_{A}>T_{C}, such that triplet state excitons of the light-emitting layer is prevented from being transmitted through the first-type blocking layer, where T_{B} is a triplet state energy level of a host material of the first-type blocking layer, T_{C} is a triplet state energy level of a host material of the light-emitting layer, T_{A} is a triplet state energy level of a first guest material of the first-type blocking layer.

2. The OLED display panel according to claim 1, wherein:
the first electrode is an anode;
the second electrode is a cathode;
HOMO_{B}−HOMO_{C}≥0.3 eV; and
HOMO_{A}−HOMO_{C}≥0.3 eV, where HOMO_{B} is a highest occupied molecular orbital energy level of the host material B of the first-type blocking layer, HOMO_{C} is a highest occupied molecular orbital energy level of the host material C of the light-emitting layer, and HOMO_{A} is a highest occupied molecular orbital energy level of the first guest material A of the first-type blocking layer.

3. The OLED display panel according to claim 1, further including:
a second function layer disposed between the first electrode and the light-emitting layer,
wherein the second function layer includes at least a second-type blocking layer, disposed adjacent to the light-emitting layer;
a second guest material is doped in a host material of the second-type blocking layer; and
a ratio of a first-type carrier mobility of the host material in the second-type blocking layer over a first-type carrier mobility of the second guest material in the second-type blocking layer is greater than or equal to about 10.

4. The OLED display panel according to claim 2, wherein:
the host material B in the first-type blocking layer includes 4,4-bis(9-carbazolyl)-1,1′-biphenyl (BCP), and
the first guest material A in the first-type blocking layer includes 2-(4-biphenyl)-5-phenyl oxadiazole (PBD).

5. The OLED display panel according to claim 1, wherein:
a content of the host material in the first-type blocking material is greater than or equal to about 90%.

6. The OLED display panel according to claim 1, wherein:
the second-type carrier mobility of the host material in the first-type blocking layer is configured to be greater than or equal to about 10⁻⁴ cm⁻²/V·S, and less than or equal to 10⁻³ cm⁻²/V·S; and
the second-type carrier mobility of the first guest material in the first-type blocking layer is configured to be less than or equal to about 10⁻⁴ cm⁻²/V·S.

7. The OLED display panel according to claim 3, wherein:
the first-type carrier mobility of the host material in the second-type blocking layer is configured to be greater than or equal to about 10⁻⁴ cm⁻²/V·S, and less than or equal to 10⁻³ cm⁻²/V·S; and
the first-type carrier mobility of the second guest material in the second-type blocking layer is configured to be less than or equal to about 10⁻⁴ cm⁻²/V·S.

8. The OLED display panel according to claim 1, wherein:
the first-type blocking layer has a thickness approximately between 1 nm and 20 nm; and
the first function layer further includes at least one of a second-type injection layer, and a second-type transport layer.

9. The OLED display panel according to claim 3, wherein:
the second function layer further includes at least one of a second-type injection layer, and a second-type transport layer.

10. The OLED display panel according to claim 1, further including a plurality of pixel regions emitting light in different colors, wherein:
the light-emitting layer corresponding to a pixel region emitting red or green light is made of a phosphorescent material; and
the light-emitting layer corresponding to a pixel region emitting blue light is made of a fluorescent material.

11. The OLED display panel according to claim 1, further including a plurality of pixel regions emitting light in different colors, wherein:
the light-emitting layer corresponding to a pixel region emitting red or blue light is made of one or two types of host materials; and
the light-emitting layer corresponding to a pixel region emitting green light is made of at least two materials.

12. The OLED display panel according to claim 1, further including a plurality of pixel regions emitting light in different colors, wherein:
a micro-cavity structure is formed between the first electrode and the second electrode in a pixel region;
a cavity length of the micro-cavity structure corresponding to the pixel region is positively correlated with a wavelength of emitted light corresponding to the pixel region; and
the cavity length of the micro-cavity structure is a distance between the first electrode and the second electrode.

13. An electronic device, comprising the OLED display panel according to claim 1.

14. A manufacturing method for the OLED display panel, comprising:
sequentially forming a first electrode, a light-emitting layer, a first function layer, and a second electrode, the light-emitting layer including a host material of the light-emitting layer and a guest material of the light-emitting layer; or
sequentially forming a second electrode, a first function layer, a light-emitting layer, and a first electrode, wherein:
the first function layer includes at least a first-type blocking layer disposed adjacent to the light-emitting layer, a first guest material is doped into a host material of the first function layer, and a ratio of a second-type carrier mobility of the host material over a second-type carrier mobility of the first guest material is greater than or equal to about 10;
the first-type is a hole-type and the second-type is an electron-type, and
T_{B}>T_{C} and T_{A}>T_{C}, such that triplet state excitons of the light-emitting layer is prevented from being transmitted through the first-type blocking layer, where T_{B} is a triplet state energy level of a host material of the first-type blocking layer, T_{C} is a triplet state energy level of a host material of the light-emitting layer, T_{A} is a triplet state energy level of a first guest material of the first-type blocking layer.

15. The manufacturing method for the OLED display panel according to claim 14, wherein:
the first electrode is an anode;
the second electrode is a cathode;
HOMO_{B}−HOMO_{C}≥0.3 eV; and
HOMO_{A}−HOMO_{C}≥0.3 eV, where HOMO_{B} is a highest occupied molecular orbital energy level of the host material B of the first-type blocking layer, HOMO_{C} is a highest occupied molecular orbital energy level of the host material C of the light-emitting layer, and HOMO_{A} is a highest occupied molecular orbital energy level of the first guest material A of the first-type blocking layer.

16. The manufacturing method for the OLED display panel according to claim 14, wherein after forming the first electrode and before forming the light-emitting layer, or after forming the light-emitting layer and before forming the first electrode, the manufacturing method further includes forming a second function layer, wherein:
the second function layer includes at least a second-type blocking layer, configured adjacent to the light-emitting layer;
a second guest material is doped in a host material of the second-type blocking layer; and
a ratio of a first-type carrier mobility of the host material in the second-type blocking layer over a first-type carrier mobility of the second guest material in the second-type blocking layer is greater than or equal to about 10.

17. The OLED display panel according to claim 1, wherein:
the host material of the light-emitting layer 1,4-bis(5-p-tert-butylphenyl-1,3,4-oxadiazolyl-2)benzene (OXD-7).
